(19) United States
(12) Patent Application Publication
(10) Pub. No.: US 2016/0084909 A1
(43) Pub. Date: Mar. 24, 2016

(54) Relay Testing Assembly

(71) Applicant: Royd Mashaney, North Pole, AK (US)

(72) Inventor: Royd Mashaney, North Pole, AK (US)

(21) Appl. No.: 14/861,607

(22) Filed: Sep. 22, 2015

Related U.S. Application Data
(60) Provisional application No. 62/053,416, filed on Sep. 22, 2014.

(51) Int. Cl. G01R 31/327

(52) U.S. Cl. CPC G01R 31/3278

(57) ABSTRACT

A relay testing assembly is provided that tests normally open and normally closed electrical relays using a testing circuit, a housing with a pair of relay connectors, and a pair of light sources that indicate to the user the condition and operation of the relay. The relay testing circuit is designed to receive power from a power source, while a switch controls power to the relay connectors for activation of the relay coil. When a relay is tested, the lights are illuminated in one of two ways to indicate the relay is operating properly, or the relay has failed to open or close the circuit, depending on the relay type. A resettable circuit breaker prevents surges in the circuit, and a transformer is optionally provided to transform AC to DC power. Overall, the tool allows rapid testing of a relay prior to installation or during maintenance.

### CROSS REFERENCE TO RELATED APPLICATION

This application claims the benefit of U.S. Provisional Application No. 62/053,416 filed on Sep. 22, 2014, entitled “Relay Tester.” The above identified patent application is herein incorporated by reference in its entirety to provide continuity of disclosure.

### BACKGROUND OF THE INVENTION

### Field of the Invention

The present invention relates to electrical relays and testing devices therefor. More specifically, the present invention relates to a relay testing device that can test single and multi-pole AC or DC relays using visual indicators.

Relays are common electrical devices. The most common relays operate using an electromagnet coil, which induces to a switch to open or close based on the magnetic field created by the coil. Relays are commonly provided having one or more poles, whereby one or more switches are operated by the relay when the relay is activated. Still others are commonly provided with one or more poles, whereby each switch in the relay controls contact between one or more circuit poles and thus provides electrical power between the one or more circuits. The common nomenclature is (1) single pole-singe throw relays, (2) single pole-double throw relays, (3) multiple pole-single throw relays, and (4) multiple pole-multiple throw relays.

Commercially available relays are provided with a connector that corresponds with the number of poles and the number of throws provided in the relay. In any of the arrangements, relays are provided in either a normally open (NO) or normally closed (NC) resting state. The resting state determines whether the circuit is open or closed when the relay is connected to a circuit and the relay coil has not been activated. Normally closed relays provide continuity across the relay when connected to a circuit, while normally open relays require the coil to be activated by a power source in order the close the circuit.

While relays are useful and common electrical devices, they require periodic replacement. In addition to periodic replacement, relays need to be checked regularly for proper operation. Like any device, relays may fail and thus not operate the circuit as designed. The present invention provides a single and multiple pole relay testing device for AC and DC circuits. Existing relays and relays to be newly installed can be quickly and efficiently tested using a power source and the circuit of the testing device, whereby visual indicators verify proper continuity across the relay. In particular, the present invention provides a housing with a relay testing circuit therein. The circuit tests normally open and normally closed relays, and the housing sidewalls provide a pair of relay connectors for both types of relays. A switch allows power to flow to the relay, and the visual indicators illuminate when the relay has successfully closed or open, depending on configuration. In this way, both normally open and normally closed relays can be tested with the same device.

### SUMMARY OF THE INVENTION

The following summary is intended solely for the benefit of the reader and is not intended to be limiting in any way. The present invention provides a new relay testing assembly that can be utilized for providing convenience for the user when testing normally open and normally closed electrical relays for proper operation.

It is therefore an object of the present invention to provide a new and improved relay testing assembly that has all of the advantages of the prior art and none of the disadvantages.

It is another object of the present invention to provide a relay testing assembly that is adapted to test normally open and normally closed electrical relays using a single assembly.

Another object of the present invention is to provide a relay testing assembly that comprises a tester housing having sidewalls and an enclosed interior volume, a first light source, a second light source, and a pair of relay connectors.

Another object of the present invention is to provide a relay testing assembly wherein the first light source, the second light source, and the pair of connectors are disposed along sidewalls of the tester housing.

Another object of the present invention is to provide a relay testing assembly that comprises a relay testing circuit that is adapted to test both normally open and normally closed relays using a connector for each type, and whereby the testing circuit illuminates one of the two light sources when the specific relay type is activated as designed.

Another object of the present invention is to provide a relay testing assembly that comprises a relay testing circuit having a power source connector adapted to connect to an alternating current or direct current power source to the testing circuit. The alternating current may be transformed into direct current using a transformer in the testing circuit.

Another object of the present invention is to provide a relay testing assembly that comprises a manually operated switch along a sidewall of the tester housing, a first relay testing socket along a sidewall of the tester housing, and a second relay testing socket along a sidewall of the tester housing.

Another object of the present invention is to provide a relay testing assembly, whereby the first relay testing socket and the second relay testing socket are electrically connected to the power source connector and the switch is between the first relay testing socket and the second relay testing socket and the power source connector.

Another object of the present invention is to provide a relay testing assembly whereby the switch operably controls a throw position of a relay positioned in one of the first relay testing socket or the second relay testing socket, and whereby the switch has a first position and a second position.

Another object of the present invention is to provide a relay testing assembly whereby the first light source and the second light source are electrically connected to the first relay testing socket and to the second relay testing socket such that each socket can illuminate both light sources when a relay is connected thereto and tested.

Another object of the present invention is to provide a relay testing assembly whereby the first relay testing socket is adapted to test normally open relays and the second relaying testing socket is adapted to test normally closed relays.

Another object of the present invention is to provide a relay testing assembly in which a normally open relay is tested using the first socket, whereby when a normally open relay is placed in connection with the first testing socket, the first light source is activated and the second light source is deactivated when the switch is the first position, and vice versa when the switch is in the second position.

Another object of the present invention is to provide a relay testing assembly in which a normally closed relay is tested using the second socket, whereby when a normally closed relay is placed in connection with the second testing socket, the first light source is deactivated and the second light source is activated when the switch is the first position, and vice versa when the switch is in the second position.

Another object of the present invention is to provide a relay testing assembly in which a resettable circuit breaker switch positioned between the power source connector and the relay testing circuit to prevent surges of power to the testing circuit or the relays.

Another object of the present invention is to provide a relay testing assembly that further comprises a transformer disposed between the power source connector and the circuit breaker, whereby the transformer is adapted to transform alternating current power to direct current power for the relay testing circuit.

Another object of the present invention is to provide a relay testing assembly that further comprises a terminal strip between the power source and the relay testing circuit to connect electrical lead wires between the switch, the sockets, and the light sources.

Other objects, features and advantages of the present invention will become apparent from the following detailed description taken in conjunction with the accompanying drawings.

### BRIEF DESCRIPTIONS OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows an embodiment of the relay testing circuit of the present invention.

FIG. 2 shows an embodiment of the tester housing of the present invention.

### DETAILED DESCRIPTION OF THE INVENTION

Reference is made herein to the attached drawings. Like reference numerals are used throughout the drawings to depict like or similar elements of the relay testing assembly of the present invention. For the purposes of presenting a brief and clear description of the present invention, the preferred embodiment will be discussed as used for testing normally open and normally closed electrical relays. The figures are intended for representative purposes only and should not be considered to be limiting in any respect.

The relay testing assembly of the present invention provides a tool that can be used to test the operation of electrical relays by activating the coil of the relay and testing the continuity across a relay testing circuit. Visual indicators are provided that the relay being tested is operating properly by opening or closing the testing circuit based on input from the tool. In particular, the testing assembly provides a first and second relay testing socket to test normally open and normally closed relays. The connector may be specific to a single or multiple pole relay design, and furthermore to single or multiple throw relays. Similarly, the testing assembly may be designed to function with an AC or DC power source. In this way, the testing circuit of the present invention can be designed to function with different types of relays, whereby the testing assembly provides a pair of relay connectors to test normally open and normally closed relays.

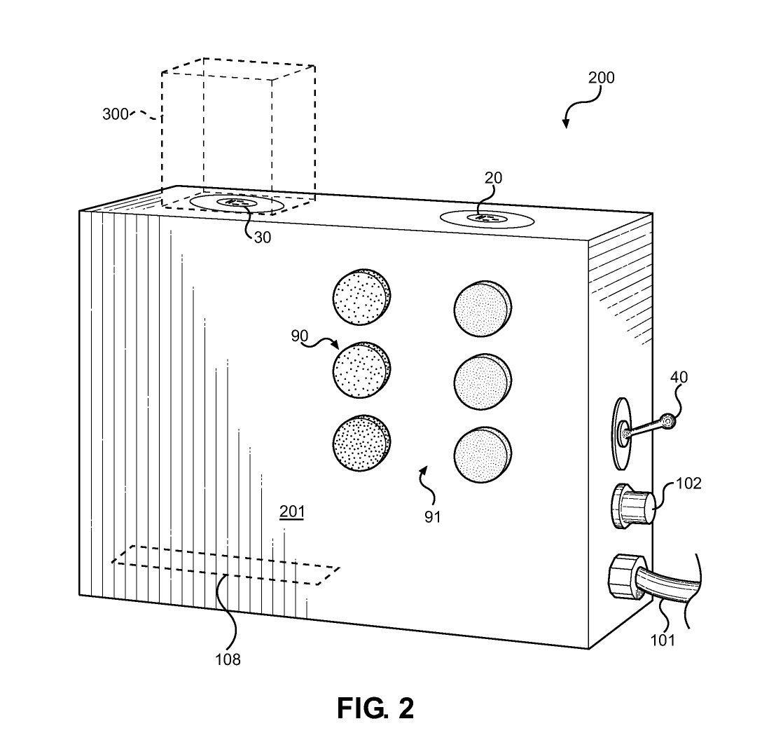

Referring to FIG. 2, there is shown a view of an embodiment of the relay testing assembly. As shown, the assembly comprises a tester housing 200 having a sidewalls 201, light sources 90, 91, a series of inputs, and a pair of relay connectors 20, 30. The relay tester housing includes a first relay connector 20 and a second relay connector 30, whereby one relay 300 is tested at a time. A relay 300 to be tested is connected to one of the connectors, whereby the connector corresponds with the type of relay being tested. In particular, the first relay testing socket 20 is adapted to test normally open relays, and the second relay testing socket 30 is adapted to test normally closed relays.

Within the interior volume of the relay tester housing is a relay testing circuit that operatively supplies power to the relay connectors such that the coil of a relay 300 connected thereto is activated, and the testing circuit is either opened or closed by the relay 300. Power is supplied to the testing circuit by a power source connector 101, which may comprise an elongated cord to an alternating power source, or may be connectors that draw power from a DC battery supply within the housing interior (not shown).

Along one of the sidewalls of the housing 200 is furthermore a manually operated switch 40, which allows the user to control current flow from the power source and to the relay sockets 20, 30. The switch 40 is thrown after a relay 300 is connected to one of the relay connectors 20, 30, whereby current is supplied to the coil of the relay, thereby opening or closing the relay switch (or switches) within the relay. This opens or closes the testing circuit, and causes one of the light sources 90, 91 to illuminate. The light sources are used in conjunction with the switch to test the continuity of the testing circuit, and thus the operation of the relay being tested. Along the housing sidewalls may further be provided a resettable circuit breaker 102, which prevents damaging surges of power to the relay and to the testing circuit.

Within the interior of the tester housing 200 are lead wires that electrically connect the power source connector 101, the circuit breaker 102, the switch 40, the light sources 90, 91, and the relay sockets 20, 30. A terminal strip 108 within the housing may be used to connect lead wires between the components of the system, whereby the terminal strip 108 provides electrical connectivity that can reduce clutter within the interior of the tester housing.

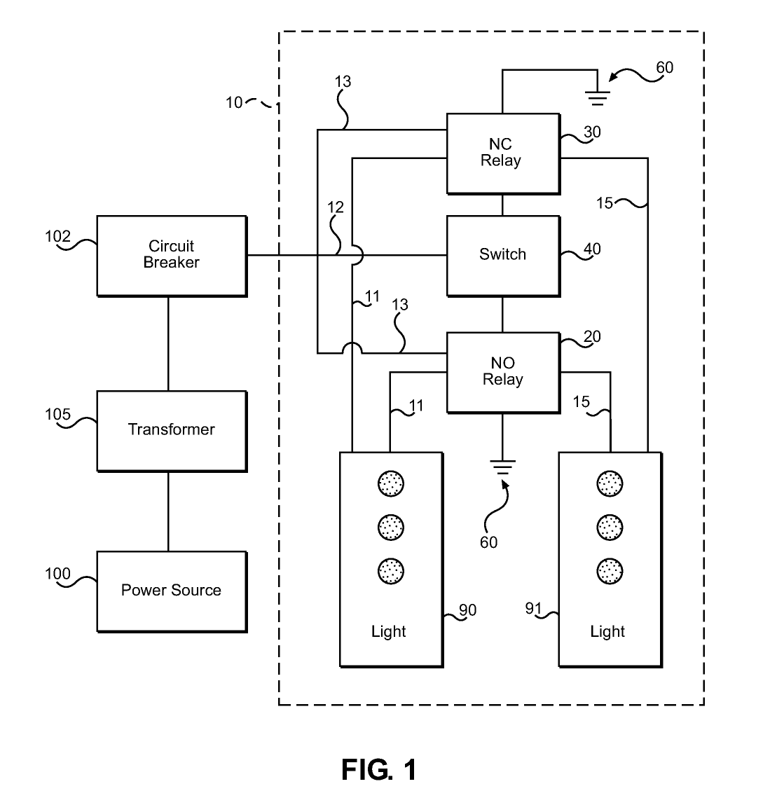

Referring now to FIG. 1, there is shown an embodiment of the relay testing circuit 10 of the present invention. The relay test circuit 10 comprises a circuit that is designed to test normally open and normally closed relays, whereby one of two light sources 90, 91 illuminates at one time to notify the user of proper relay operation. A power source connector 100 is provided to connect to a power source to the circuit 10 and route electrical power thereto. Between the power source and the circuit 10 is an optional AC to DC transformer 105 and a resettable circuit breaker 102. The transformer transforms AC input power to DC power for the circuit 10, and the circuit breaker 102 is a resettable device that breaks continuity with the circuit 10 if a surge of current is detected, thereby preventing damage to downstream components of the circuit 10.

The testing circuit 10 comprises a manually operated switch 40 that receives current from a power source lead 12 connected to the power source connector 100. The lead 12 may be connected to an external power source, and thus require the power source connector, or optionally an internal battery power source within the housing may supply power to the power source lead 12. Downstream of the switch 40 is a first relay testing socket 20 and a second relay testing socket 30. The first relay testing socket 20 is designed to test normally open (NO) relays, while the second relay testing socket 30 is designed to test normally closed (NC) relays. The sockets are connectors that accept the prongs of a relay connected thereto, where the specific socket employed may have a plurality of prongs for multiple pole relays. The exact sockets provided may vary based on the design of the testing assembly and the needs of the user.

The first relay testing socket 20 and the second relay testing socket 30 are electrically connected to the power source and are controlled by the switch 40. The switch 40 is used to induce the coil of the first testing socket 20 or the second relay testing socket 30, whereby the coil activates in one of the two sockets, depending on the position of the switch 40. The type of relay will determine whether the coil induces a closure of the circuit or opening of the circuit. For instance, power supplied by the switch 40 to the first socket 20 is designed to induce the coil of a normally open relay to close the circuit. Furthermore, power supplied to the second socket 30 by the switch 40 is designed to induce the coil of a normally closed relay to open the circuit. Therefore, the two sockets are suited for different relay types and the switch 40 controls activation of the relay coil in the socket.

Power is supplied to the relays by separate lead lines 13. When the relay being tested in the particular socket 20, 30 closes the circuit, current flows from the power source 100, through the relay socket, through the closed relay, and into one of the light sources 90, 91. Downstream of the relay sockets 20, 30 is a first and second light source lead 11, 15. The first light source lead 11 connects the relay sockets to the first light source 90, and the second light source lead 15 connects the relay sockets to the second light source 91. In this way, both sockets 20, 30 connect to both light sources 90, 91. The light sources are designed to signify to the user that the particularly relay has closed or opened when the switch 40 activates the particular relay. In this way, the switch operably controls the throw position of a relay positioned in one of the first relay testing socket or the second relay testing socket. The switch has a first position and a second position, whereby the relay is placed into a socket and the switch is used to activate and deactivate the coil thereof, which activates one light source at a time. When the circuit is closed, one of the light sources is illuminated. When the circuit is open, the opposite light source is illuminated. The wiring of the sockets and the throw position of the switch 40 signifies to the user the coil of the relay is operational and continuity is being provided across its prongs.

During operation, the first relay testing socket 90 is adapted to test normally open relays, whereby when a normally open relay is connected to the first relay testing socket 20, the first light source 90 is activated and the second light source 91 is deactivated when the switch 40 is the first position. When the switch is in its second position, the coil changes state and the first light source 90 is deactivated and the second light source 91 is activated. Similarly, the second relay testing socket 30 is adapted to test normally closed relays, whereby when a normally closed relay is connected to the second relay testing socket 30, the first light source 90 is deactivated and the second light source 91 is activated when the switch 40 is the first position. When the switch 40 flipped into its second position, the first light source 90 is activated and the second light source 91 is deactivated. The first and second light sources are preferably arranged separately, and/or include different color lights to indicate to the user the state of the relays and the continuity across the testing circuit. Electrical grounding 60 is provided in the system for proper operation of the circuit.

Overall, it is submitted that the instant invention has been shown and described in what is considered to be the most practical and preferred embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1. A relay testing device, comprising:
a tester housing having sidewalls and an enclosed interior volume;
a first light source disposed along a sidewall of the tester housing;
a second light source disposed along a sidewall of the tester housing;
a relay testing circuit comprising:
a power source connector adapted to connect to a power source and route electrical power to the relay testing circuit;
a manually operated switch along a sidewall of the tester housing;
a first relay testing socket along a sidewall of the tester housing;
a second relay testing socket along a sidewall of the tester housing;
the first relay testing socket and the second relay testing socket being electrically connected to the power source connector;
whereby the switch is between the first relay testing socket and the second relay testing socket and the power source connector;
the switch operably controlling a throw position of a relay positioned in one of the first relay testing socket or the second relay testing socket;
the switch having a first position and a second position;
the first light source and the second light source electrically connected to the first relay testing socket;
the first light source and the second light source electrically connected to the second relay testing socket;
whereby the first relay testing socket is adapted to test normally open relays, whereby when a normally open relay is connected to the first relay testing socket, the first light source is activated and the second light source is deactivated when the switch is the first position, and furthermore wherein the first light source is deactivated and the second light source is activated when the switch is in the second position;
whereby the second relay testing socket is adapted to test normally closed relays, whereby when a normally closed relay is connected to the second relay testing socket, whereby the first light source is deactivated and the second light source is activated when the switch is the first position, and furthermore wherein the first light source is activated and the second light source is deactivated when the switch is in the second position;
a resettable circuit breaker switch positioned between the power source connector and the relay testing circuit.

2. The relay testing device of claim 1, further comprising a transformer disposed between the power source connector and the circuit breaker, whereby the transformer transforms alternating current power to direct current power for the relay testing circuit.

3. The relay testing device of claim 1, further comprising a terminal strip between the power source and the relay testing circuit.
